(19) United States
(12) Patent Application Publication
(10) Pub. No.: US 2005/0184818 A1
(43) Pub. Date: Aug. 25, 2005

(54) High frequency oscillator using dielectric resonator

(76) Inventors: Masayoshi Aikawa, Saga (JP); Takayuki Tanaka, Saga (JP); Fumio Asamura, Saitama (JP); Takeo Oita, Saitama (JP)

Correspondence Address: PATENT GROUP;CHOATE, HALL & STEWART, EXCHANGE PLACE, 53 STATE STREET, BOSTON, MA, 02109, US

(21) Appl. No.: 11/046,542

(22) Filed: Jan. 28, 2005

(30) Foreign Application Priority Data
Jan. 29, 2004 (JP) 2004-020757

(51) Int. Cl. H03B 5/18

(52) U.S. Cl. 331/107 SL

(57) ABSTRACT

A second-harmonic oscillator based on push-push oscillation has a pair of amplifiers for oscillation, a high frequency transmission line for connecting inputs of the pair of amplifiers to each other and connecting outputs of the pair of amplifiers to each other, and an electromagnetic coupling member disposed between the inputs and outputs of the pair of amplifiers such that it is electromagnetically coupled to the high frequency transmission line. The electromagnetic coupling member includes at least a dielectric resonator. The pair of amplifiers, high frequency transmission line, and electromagnetic coupling member form two oscillation loops which oscillate in opposite phases to each other with respect to a fundamental wave of oscillation for generating a second harmonic of the fundamental wave.

### BACKGROUND OF THE INVENTION

1. Field of the Invention

The present invention relates to a high frequency oscillator for use in a millimeter-wave band, a microwave band and the like, and more particularly, to a high frequency oscillator which can generate an output at a frequency twice as high as a fundamental wave of an oscillation frequency through so-called push-push oscillation.

2. Description of the Related Art

A push-push oscillation based oscillator is known as suitable for generating oscillation signals in a millimeter-wave band and a microwave band. The oscillator based on push-push oscillation employs a pair of oscillation circuits which operate at the same fundamental frequency but in opposite phases to each other, and combines the outputs from these oscillation circuits to cancel out the fundamental wave components and extract even-order harmonic components to the outside. Such push-push oscillators are used in a variety of applications because of its simple configuration and its ability to generate output frequencies twice or more as high as fundamental wave f0, and are useful, for example, as an oscillation source for a high frequency network which operates, for example, in association with fiber-optic cables, or as an oscillation source for measuring devices. The present inventors have proposed, for example, in Japanese Patent Laid-open Publication No. 2004-96693 (JP, P2004-96693A) a high frequency oscillator which is further reduced in size to facilitate its design and generates, for example, even-order harmonics such as a second harmonic 2f0 or higher for fundamental wave f0.

FIG. 1A is a plan view illustrating the configuration of a conventional second-harmonic oscillator for generating a frequency component twice as high as a fundamental wave, i.e., a second harmonic component, and FIG. 1B is a cross-sectional view taken along line A-A in FIG. 1A.

Generally, a second-harmonic planar oscillator comprises a pair of amplifiers 3a, 3b for oscillation; microstrip line 1 which serves as a high frequency transmission line within oscillation systems; and slot line 2 for coupling. Slot line 2 functions as an electromagnetic coupling member for causing the two oscillation systems to oscillate in opposite phases to each other.

Microstrip line 1 for oscillation is routed on one principal surface of dielectric substrate 5, and ground conductor 6 is formed substantially over the entirety of the other principal surface of dielectric substrate 5. Here, microstrip line 1 is formed in a closed loop substantially in a rectangular shape.

The pair of amplifiers 3a, 3b for oscillation, each comprised of an FET (Field Effect Transistor) or the like, have their output terminals disposed on the one principal surface of dielectric substrate 5 in a mutually opposing relationship, and are inserted in microstrip line 1. In this way, microstrip line 1 connects input terminals of the pair of amplifiers 3a, 3b for oscillation to each other, and the output terminals of the same to each other. In the figure, microstrip line 1 consists of microstrip line portion 1a and microstrip line portion 1b, microstrip line portion 1a connects the input terminals of the pair of amplifier 3a, 3b, and microstrip line portion 1b connects the output terminals of the pair of amplifier 3a, 3b.

Slot line 2 is implemented by an aperture line formed in ground conductor 6 on the other principal surface of substrate 5, and is routed to vertically traverse two sections in central portions of microstrip line 1 which is routed on the one principal surface of substrate 5. Slot line 2 extends upward and downward by λ/4 respectively from the sections of microstrip line 1 which are traversed by slot line 2, where λ represents the wavelength corresponding to an oscillation frequency (i.e., fundamental wave f0), later described. Output microstrip line 4 is routed on the one principal surface of substrate 5 and superimposed on slot line 2. Output microstrip line 4 is connected to the center of microstrip line portion 1b (the lower side in the figure) which connects between the outputs of the pair of amplifiers 3a, 3b for oscillation.

In the foregoing oscillator, microstrip line 1 is electromagnetically coupled to slot line 2 to form two oscillation systems, as shown in the left and right halves of the figures. In this configuration, a high frequency signal in an unbalanced propagation mode, which propagates through microstrip line 1, is converted into a balanced propagation mode of slot line 2. Since the balanced propagation mode of slot line 2 involves a propagation which presents opposite phases at both sides of aperture line 2A, eventually causing the two oscillation systems to oscillate in opposite phases to each other. Since the oscillation frequency (fundamental wave f0) in the oscillation systems generally depends on the length of each oscillation closed loop, the oscillation systems are designed such that the respective oscillation systems oscillate at the same oscillation frequency.

In the configuration as described above, at the midpoint of microstrip line 1 which connects between the outputs of the pair of amplifiers 3a, 3b to each other, the fundamental wave (f0) component and odd-order harmonic components in the oscillation frequencies are in opposite phases to each other to provide null potential. On the other hand, even-order harmonics of a second harmonic or higher harmonics are combined for delivery. However, since higher harmonic components of a fourth harmonic or higher have relatively low levels as compared with the second harmonic component, the fundamental wave f0 and other harmonics are suppressed to provide the second harmonic 2f0 on output line 4.

Since slot line 2 is extended by a quarter wavelength relative to fundamental wave f0 from the upper and lower sections of microstrip line 1, the respective ends of slot line 2 are electrically open ends, viewed from the positions at which slot line 2 traverses microstrip line 1. Therefore, the oscillation component of fundamental wave f0 is efficiently transmitted to a positive feedback loop through slot line 2, thus increasing the Q-value of the oscillator circuit. The length λ/4, by which slot line 2 is extended, need not be strictly equal to λ/4 because this may be such a length that permits the ends of slot line 2 to be regarded as electrically open ends.

However, in the second-harmonic oscillator in the foregoing configuration, the oscillation frequency (fundamental frequency f0) of each oscillation system is determined depending on the length of the closed loop, but the Q-value is relatively small, causing a problem of a lower frequency stability. Thus, an attempt has been made to increase the frequency stability by operating such a second-harmonic oscillator through injection synchronization.

FIG. 2 is a plan view illustrating a second-harmonic oscillator which employs the injection synchronization. The second-harmonic oscillator illustrated in FIG. 2. though similar to that illustrated in FIG. 1, differs in that signal line 8 for injecting a synchronization signal is connected to the midpoint of microstrip line portion 1a, which connects between inputs of a pair of amplifiers 3a, 3b for oscillation. Signal line 8 has a microstrip line structure, and is muted to overlap on slot line 2. In this second-harmonic oscillator, a synchronization signal at frequency f0/n is injected from signal line 8 into microstrip line 1, where n is an integer equal to or more than two, and f0 is the fundamental wave of the oscillation frequency of the oscillator. As a result, the oscillator oscillates in synchronization with the synchronization signal, thus increasing the frequency accuracy of the second-harmonic oscillator to a similar level of the frequency accuracy of the synchronization signal. The frequency stability of the second-harmonic oscillator can be improved by generating a synchronization signal from an oscillation source, for example, a crystal oscillator and the like, which exhibits a high frequency stability. However, the injection synchronization requires a synchronization signal source and the like, resulting in a complicated circuit configuration.

### SUMMARY OF THE INVENTION

It is therefore an object of the present invention to provide a second-harmonic oscillator which exhibits a high frequency stability even without employing the injection synchronization.

It is another object of the present invention to provide a second-hamionic oscillator which is capable of further improving the frequency stability and oscillation stability by employing the injection synchronization.

The objects of the present invention is achieved by a high frequency resonator which includes a pair of amplifiers for oscillation, a high frequency transmission line for connecting inputs of the pair of amplifiers to each other and connecting outputs of the pair of amplifiers to each other, and an electromagnetic coupling member disposed between inputs and outputs of the pair of amplifiers such that said electromagnetic coupling member is electromagnetically coupling with the high frequency transmission line, wherein the electromagnetic coupling member includes at least a dielectric resonator, and the pair of amplifiers, high frequency transmission line, and electromagnetic coupling member form two oscillation loops which oscillate in opposite phases to each other with respect to a fundamental wave of oscillation for generating an even-order harmonic of the fundamental wave.

According to the present invention, since the dielectric resonator is used for the electromagnetic coupling member which is electromagnetically coupled to the high frequency transmission line. the Q-value in the oscillation systems can be increased to provide a higher frequency stability.

In the present invention, preferably, the high frequency transmission line used herein is a microstrip line which comprises a signal line on one principal surface of a substrate, and a ground conductor on the other principal surface of the substrate.

Also, in the present invention, the electromagnetic coupling member can be made up of a dielectric resonator and a slot line which is arranged in the ground conductor. The slot line traverses the microstrip line and is electromagnetically coupled to the dielectric resonator. When the slot line is used, the length from a point at which the slot line traverses the microstrip line to the leading end of the slot line may be set to approximately one quarter of the wavelength of the fundamental wave. With this setting, the slot line can be regarded as an electrically open end, as viewed from the transverse point, thereby increasing the oscillation efficiency.

### BRIEF DESCRIPTION OF THE DRAWINGS

FIG. 1A is a plan view illustrating the configuration of a conventional second-harmonic planar oscillator which generates a frequency component twice as high as a fundamental wave, i.e., a second-harmonic component;

FIG. 1B is a cross-sectional view taken along line A-A in FIG. 1A;

FIG. 2 is a plan view illustrating the configuration of a conventional second-harmonic planar oscillator which employs injection synchronization;

FIG. 3A is a plan view illustrating the configuration of a second-harmonic oscillator according to a first embodiment of the present invention;

FIG. 3B is a cross-sectional view taken along line A-A in FIG. 3A;

FIG. 4A is a plan view illustrating the configuration of a second-harmonic oscillator according to a second embodiment of the present invention;

FIG. 4B is a cross-sectional view taken along line A-A in FIG. 4A;

FIG. 5A is a plan view illustrating another exemplary configuration of the second-harmonic oscillator according to the second embodiment;

FIG. 5B is a cross-sectional view taken along line A-A in FIG. 5A;

FIG. 6 is a plan view illustrating the configuration of a second-harmonic oscillator according to a third embodiment of the present invention;

FIG. 7 is a plan view illustrating the configuration of a second-harmonic oscillator according to a fourth embodiment of the present invention which employs the injection synchronization; and

FIG. 8 is a plan view illustrating another exemplary configuration of the second-harmonic oscillator according to the fourth embodiment.

### DETAILED DESCRIPTION OF THE PREFERRED EMBODIMENTS

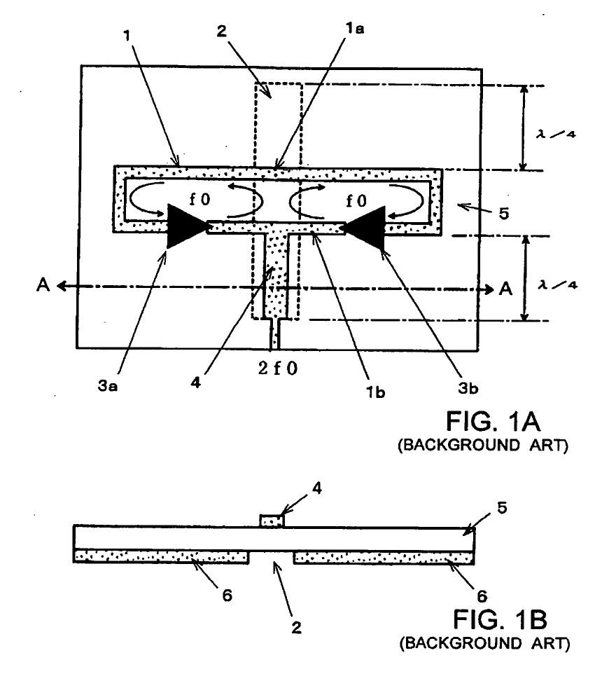

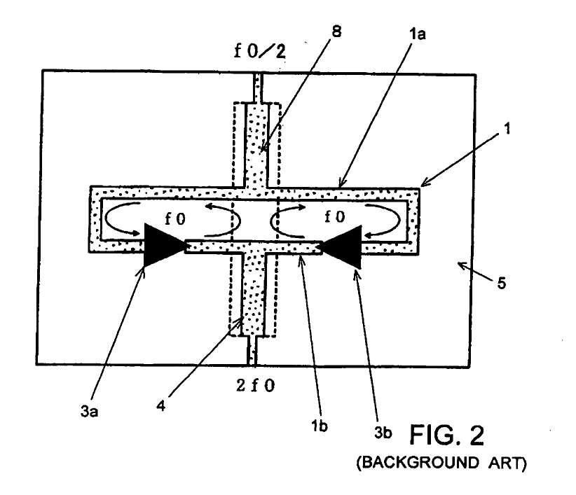

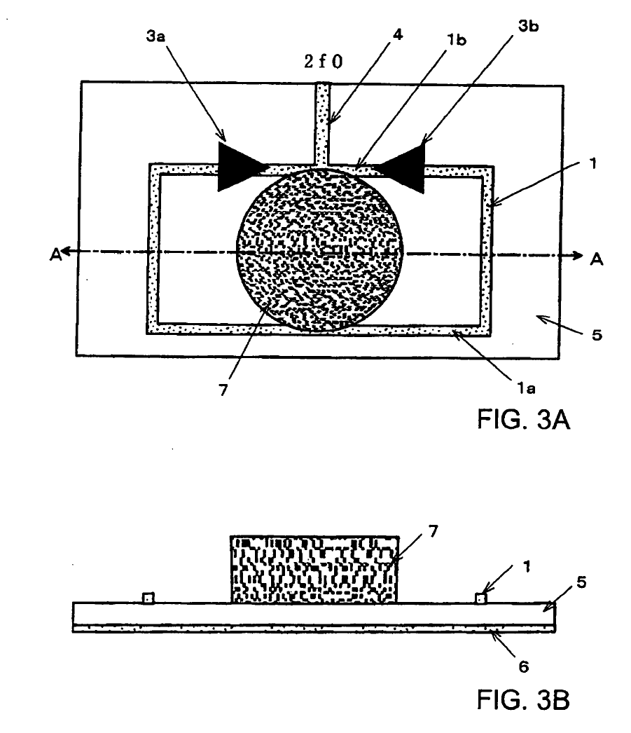

A second-harmonic oscillator according to a first embodiment of the present invention illustrated in FIGS. 3A and 3B comprises dielectric resonator 7 instead of the slot line in the oscillator illustrated in FIGS. 1A and 1B. In FIGS. 3A and 3B, components identical to those in FIGS. 1A and 1B are designated the same reference numerals, and repeated description thereon is simplified.

The second-harmonic oscillator illustrated in FIGS. 3A and 3B, like the one illustrated in FIGS. 1A and 1B, comprises a pair of amplifiers 3a, 3b for oscillation; microstrip line 1 as a high frequency transmission line; output line 4 in microstrip line structure for an oscillation output; and dielectric substrate 5. Amplifiers 3a, 3b, microstrip line 1, and output line 4 are all disposed on one principal surface of dielectric substrate 5, while ground conductor 6 is disposed over the entirety of the other principal surface of dielectric substrate 5. Microstrip line 1 is routed in a rectangular shape such that a closed loop is formed by microstrip line 1 and amplifiers 3a, 3b. Here, a section of microstrip line 1 formed in a rectangular loop shape, which corresponds to the upper side of the rectangle in the figure, is called the “upper side section,” while a section corresponding to the lower side of the rectangle is called the “lower side section.” In the illustrated example, amplifiers 3a, 3b for oscillation are inserted in the upper side section such that their output terminals oppose each other. Output line 4 is drawn out substantially from the midpoint of the upper side section.

Dielectric resonator 7 is disposed on the one principal surface of dielectric substrate 5 such that it is electromagnetically coupled to microstrip line 1 in the upper side section and lower side section of microstrip line 1. Dielectric resonator 7, which is made of ceramics formed, for example, in a cylindrical shape, has its outer periphery in contact with microstrip line 1 near the midpoint of the upper side section and near the midpoint of the lower side section. in other words, dielectric resonator 7 has edge portions which overlap microstrip line 1 on the upper side section and the lower side section, respectively. The resonant frequency of dielectric resonator 7 is set at the fundamental frequency of the oscillation of the oscillator, i.e., fundamental wave f0.

In the configuration as described above, microstrip line 1 is electromagnetically coupled to dielectric resonator 7 on the upper side section and lower side section, as illustrated, so that two oscillation systems are formed in the left and right halves, as viewed in the figures, in a manner similar to the conventional oscillator illustrated in FIGS. 1A and 1B. Specifically, the two oscillation systems formed herein include an oscillation system comprised of a left half, as viewed in the figure, of microstrip line 1, amplifier 3a, and dielectric resonator 7, and another oscillation system comprised of a right half, as viewed in the figure, of microstrip line 1, amplifier 3b, and dielectric resonator 7.

In this configuration, an inducted current is excited in microstrip line 1 by a magnetic field from dielectric resonator 7. This inducted current flows through the left side and right side of loop-shaped microstrip line 1 in directions opposite to each other. Also, in regard to the upper side section, the inducted current flows in the same direction on both sides of the point of microstrip line 1 which is in contact with dielectric resonator 7. Likewise, in regard to the left side section, the inducted current flows in the same direction on both sides of the point of microstrip line 1 which is in contact with dielectric resonator 7. Therefore, in consideration of the upper side section or lower side section, the left and right oscillation systems generate the inducted currents in opposite phases to each other, so that the two oscillation systems oscillate in opposite phases to each other. In this event, dielectric resonator 7 functions as an electromagnetic coupling member for causing the left and right oscillation systems to oscillate in opposite phases to each other.

In the configuration as described above, at the midpoint of the upper side section of microstrip line 1 which connects between the outputs of the pair of oscillators 3a, 3b for oscillation, the fundamental wave ( f0) component and odd-order harmonic components of the oscillation frequencies are in opposite phases to each other and cancel out to provide null potential. Even-order harmonics of a second-harmonic or higher are combined for delivery. However, since even-order harmonics of a fourth harmonic and higher are relatively low in level as compared with the second harmonic, fundamental wave f0 and other harmonics are suppressed, with the result that second harmonic 2f0 remains on output line 6. Also, since dielectric resonator 7 is commonly inserted into each of the oscillation systems as an electromagnetic coupling member, a high Q-value of dielectric resonator 7 helps increase the frequency stability of second harmonic 2f0.

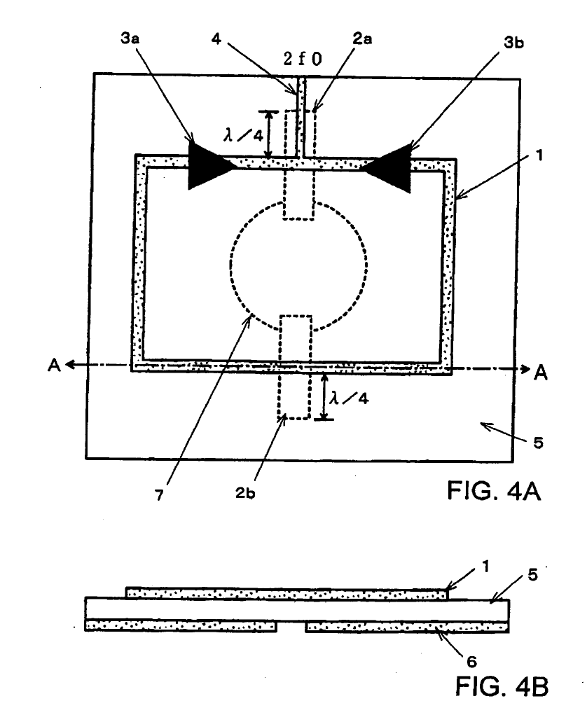

Next, description will be made on a second-harmonic oscillator according to a second embodiment of the present invention. The second-harmonic oscillator according to the second embodiment, as illustrated in FIGS. 4A and 4B, differs from the second-harmonic oscillator according to the first embodiment in that the second embodiment employs dielectric resonator 7 which has a diameter smaller than the spacing between the upper side section and lower side section of microstrip line 1, and slot lines 2a, 2b formed on the other principal surface of dielectric substrate 5 for electromagnetically coupling dielectric resonator 7 to microstrip line 1. Dielectric resonator 7 is mounted on the other principal surface of dielectric substrate 5. Slot line 2a is formed to traverse the upper side section of microstrip line 1 for electromagnetic coupling thereto, and extend approximately by λ/4 upward, as viewed in the figure, from the point at which slot line 2a traverses microstrip line 1, where λ is the wavelength corresponding to fundamental wave f0. Similarly, slot line 2b is formed to traverse the lower side section of microstrip line 1 for electromagnetic coupling thereto, and extend approximately by λ/4 downward, as viewed in the figure, from the point at which slot line 2b traverses microstrip line 1. As shown in the figure, the lower end of slot line 2a and the upper end of slot line 2b contact upper end portion and lower end portion of the periphery of dielectric resonator 7, respectively. Slot lines 2a, 2b are thus electromagnetically coupled with dielectric resonator.

With the configuration as described above, slot lines 2a, 2b and dielectric resonator 7 function as an electromagnetic coupling member for coupling the upper side section to the lower side section of microstrip line 1, thus resulting in the formation of two oscillation systems which oscillate in opposite phases to each other, as is the case with the first embodiment. In this event, slot lines 2a, 2b convert a signal in unbalanced propagation mode, which propagates through microstrip line 1, into a balanced propagation mode. In each of slot lines 2a, 2b, inducted currents are generated in opposite phases to each other in ground conductor 6 on both sides of the opening of the slot line. Also, electric fields run in opposite directions to each other in slot lines 2a, 2b.

Similar to the first embodiment, in the second-harmonic oscillator of the second embodiment, fundamental wave f0 and odd-order harmonics are canceled out to generate a second harmonic 2f0, which has the highest level of even-order harmonics, on output line 4. Also, the use of dielectric resonator 7 10 contributes to an increased frequency stability. Further, since each of slot lines 2a, 2b herein extends approximately by λ/4 from a point at which it traverses microstrip line 1, the extension is regarded as an electrically open end with respect to the fundamental wave (f0) component, as viewed from the traverse point, thus increasing the oscillation efficiency at fundamental wave f0 in each oscillation system.

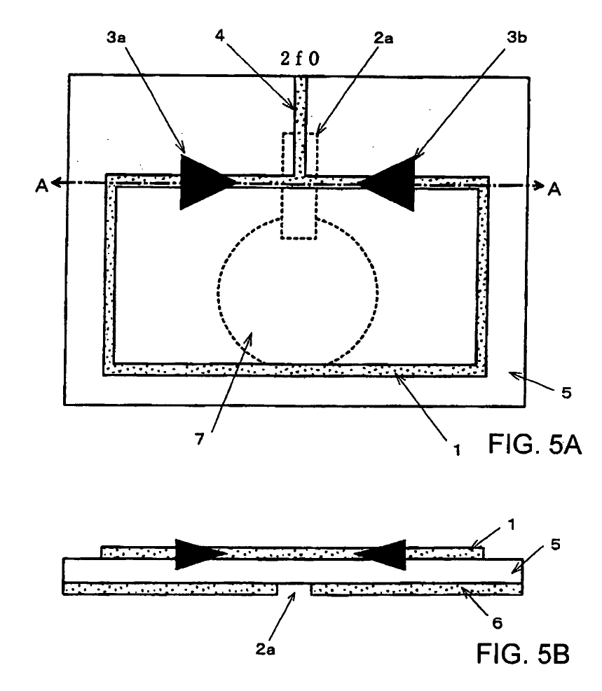

Alternatively, in the second embodiment, one of slot lines 2a, 2b may be removed, and instead, dielectric resonator 7 may be electromagnetically coupled directly to microstrip line 1. FIGS. 5A and 5B illustrate such a double-wave oscillator. In the illustrated second-harmonics oscillator, slot line 2a remains coupled to the upper side section of microstrip line 1, whereas slot line 2b, which would otherwise would be coupled to the lower side section, has been removed. Instead, dielectric resonator 7 overlies microstrip line 1 in contact therewith for electromagnetic coupling to microstrip line 1 near the midpoint of the lower side section of microstrip line 1. Such a second-harmonic oscillator can provide similar advantages to those of the oscillator illustrated in FIGS. 4A and 4B.

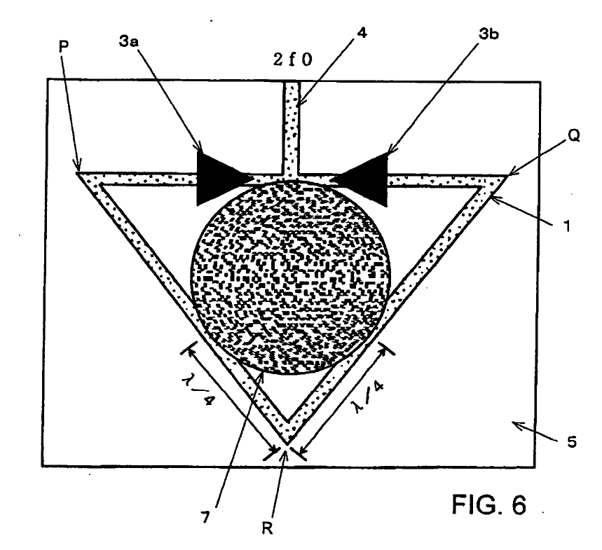

Next, description will be made on a second-harmonic oscillator according to a third embodiment of the present invention. In the first and second embodiments, microstrip line 1 has been routed to form a rectangular closed loop, but microstrip line 1 is not limited in shape to that shown in the foregoing embodiments. In the oscillator according to the third embodiment illustrated in FIG. 6, microstrip line 1 is muted in a triangular shape. Specifically, in the oscillator illustrated in FIG. 6, the configuration of the first embodiment is modified such that, though the upper side section of microstrip line 1 remains unchanged, microstrip line 1 is extended obliquely from both ends P, Q of the upper side section, respectively, and the obliquely extended sections are connected at apex R. Then, the outer periphery of dielectric resonator 7 is inscribed in a triangle formed by microstrip line 1, so that dielectric resonator 7 is in contact with microstrip line 1 at three points. In this configuration, the outer periphery of dielectric resonator 7 is in contact with microstrip line 1 at the midpoint between the outputs of amplifiers 3a, 3b, at a position on side PR approximately λ/4 away from point R, and at point on side QR approximately λ/4 from point R.

With the configuration as described above, microstrip line 1 is electromagnetically coupled to dielectric resonator 7 at three points, and inducted currents are generated in opposite phases to each other at the coupled point on side PR and at the coupled point on side QR. These inducted currents are fed back to amplifiers 3a, 3b for oscillation. Also, since the distances are both λ/4 from coupled points on the two oblique sides of microstrip line 1 with dielectric resonator 7 to point R, respectively, point R is at null potential, so that point R appears to be an infinite impedance point, when viewed from the coupled points.

Likewise, in the second-harmonic oscillator according to the third embodiment, the fundamental wave (f0) component is not delivered from output line 4 but the second-harmonic (2f0) component is delivered, as is the case with the respective oscillators of the aforementioned embodiments.

Next, description will be made on a second-harmonic oscillator according to a fourth embodiment of the present invention. The second-harmonic oscillator according to the present invention can also employ the injection synchronization, and can further improve the frequency stability with the employment of the injection synchronization.

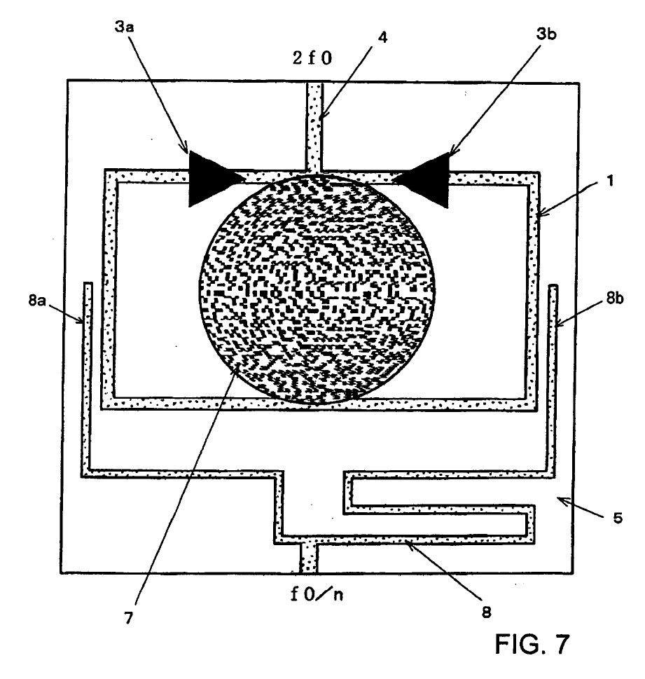

The second-harmonic oscillator according to the fourth embodiment illustrated in FIG. 7 is a modification to the oscillator according to the first embodiment, which is made to permit the application of the injection synchronization. In the illustrated configuration, the injection synchronization involves injecting synchronization signals in opposite phases to each other into the left and right oscillation systems. Specifically, microstrip line 8 is routed for injecting the synchronization signals, and is branched into microstrip lines 8a, 8b at one end thereof, while the synchronization signals are supplied to the other ends of the branches. The leading end of microstrip line 8a is placed in close proximity to the left side section of microstip line 1 formed in a rectangular closed loop to bring microstrip line 8a into electromagnetic coupling to the left side section. Similarly, the leading end of microstrip line 8b is placed in close proximity to the right side section of microstrip line 1 formed in a rectangular closed loop to bring microstrip line 8b into electromagnetic coupling to the right side section. Microstrip line 8a differs in length from microstrip line 8b by λ/2 such that the left and right oscillation systems are injected with synchronization signals in opposite phases to each other, as converted to fundamental wave f0, where the fundamental wave of the oscillator is at frequency f0, and λ is the wavelength corresponding to f0. The synchronization signals used herein are at frequency f0/n, where n is an integer equal to or larger than one.

In this double-wave oscillator, the left and right oscillation systems are applied with the synchronization signals in opposite phases to each other, as converted to fundamental wave f0, and oscillate such that the fundamental wave component is synchronized to the synchronization signal at time intervals of n/f0, thus making it possible to further increase the frequency stability of the oscillator by use of the synchronization signals which exhibit a high frequency stability.

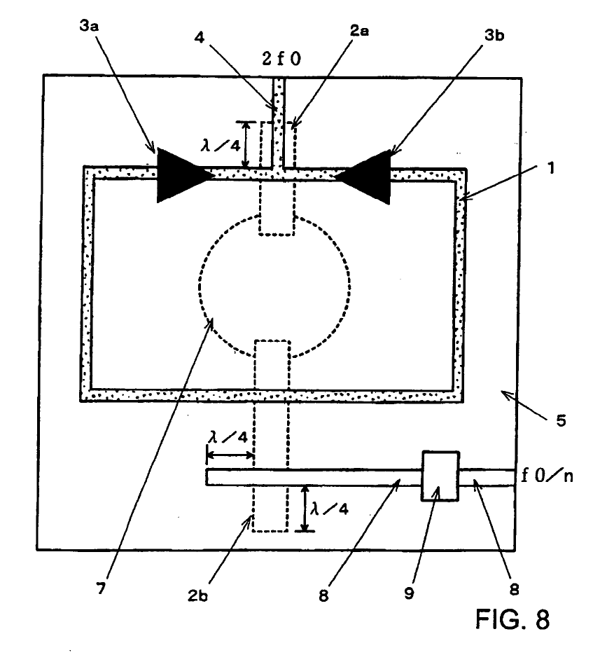

It should be understood that the way of injecting the synchronization signals is not limited that illustrated in FIG. 7. When a second-harmonic oscillator has a slot line, the synchronization signal can be injected into the slot line. FIG. 8 illustrates such an oscillator.

The second-harmonic oscillator illustrated in FIG. 8 is a modification to the second-harmonic oscillator illustrated in FIGS. 4A and 4B, which is made to inject a synchronization signal into slot line 2b. Microstrip line 8 for injecting the synchronization signal is routed to traverse slot line 2b, with its leading end extending by λ/4 from the point at which microstrip line 8 traverses slot line 2b. The lower end of slot line 2b, as viewed in the figure, also extends by λ/4 from that point. As illustrated, non-linear circuit or frequency multiplier circuit 9 is inserted halfway in microstrip line 8 for injecting the synchronization signals in order to generate the fundamental wave (f0) component from the synchronization signal at frequency f0/n.

The second-harmonic oscillator illustrated in FIG. 8 is similar to the oscillator illustrated in FIG. 7 in the ability to further increase the frequency stability of the oscillator.

While a preferred embodiment of the present invention has been described above, the high frequency transmission line used herein for connecting between the inputs of the pair of amplifiers for oscillation and connecting between the outputs of the pair of amplifiers may be, for example, a coplanar line, or a combination of a coplanar line and a microstrip line instead of the aforementioned microstrip line 1.

Also, since the second-harmonic oscillator of the present invention comprises the oscillator circuit placed on the dielectric substrate, and the dielectric resonator attached thereto, the oscillator circuit itself may be incorporated in MMIC (Monolithic microwave integrated circuit) with the dielectric resonator placed thereon.

1. A high frequency oscillator comprising:
a pair of amplifiers for oscillation;
a high frequency transmission line for connecting inputs of said pair of amplifiers to each other and connecting outputs of said pair of amplifiers to each other; and
an electromagnetic coupling member disposed between the inputs and the outputs of said pair of amplifiers such that said electromagnetic coupling member is electromagnetically coupling with said high frequency transmission line,
wherein said electromagnetic coupling member includes at least a dielectric resonator, and
said pair of amplifiers, said high frequency transmission line, and said electromagnetic coupling member form two oscillation loops which oscillate in opposite phases to each other with respect to a fundamental wave of oscillation for generating an even-order harmonic of the fundamental wave.

2. The oscillator according to claim 1, further comprising an output line connected to said high frequency transmission line at position of said high frequency transmission line at which said electromagnetic coupling member couples said high frequency transmission line, said position of said high frequency transmission line being located between said inputs of said pair of amplifiers or between said outputs of said pair of amplifiers.

3. The oscillator according to claim 1, wherein said high frequency transmission line comprises a microstrip line which has a signal line on one principal surface of a substrate, and a ground conductor on the other principal surface of said substrate.

4. The oscillator according to claim 3, wherein said dielectric resonator has an edge portion on which overlaps on said microstrip line thereby electromagnetically coupling to the microstrip line.

5. The oscillator according to claim 3, wherein said electromagnetic coupling member further includes a slot line arranged within said ground conductor and routed to traverse said microstrip line, and said slot line is electromagnetically coupled to said dielectric resonator.

6. The oscillator according to claim 5, wherein said dielectric resonator has an edge portion on which overlaps on said microstrip line thereby electromagnetically coupling to the microstrip line.

7. The oscillator according to claim 3, wherein said electromagnetic coupling member includes a first slot line arranged within said ground conductor and routed to traverse said microstrip line at a first position, and a second slot line arranged within said ground conductor and routed to traverse said microstrip line at a second position different from the first position, and said first slot line and said second slot line are electromagnetically coupled to said dielectric resonator.

8. The oscillator according to claim 1, wherein said even-order harmonic is a second harmonic.

9. The oscillator according to claim 1, further comprising a pair of microstrip lines electromagnetically coupled to said two oscillation closed loops, respectively, for injecting signals in opposite phases to each other into said oscillation loops, wherein said signals injected into said oscillation loops are synchronization signals at a frequency 1/n as high as a frequency corresponding to said fundamental wave, and n is an integer equal to or larger than one.
